(19) United States
(12) Patent Application Publication
(10) Pub. No.: US 2024/0110786 A1
(43) Pub. Date: Apr. 4, 2024

(54) METHOD FOR MANUFACTURING VIBRATOR

(71) Applicant: SEIKO EPSON CORPORATION, Tokyo (JP)

(72) Inventors: Hiyori Sakata, Shinagawa-ku (JP); Keiichi Yamaguchi, Ina-shi (JP); Ryuta Nishizawa, Nagano-shi (JP); Shigeru Shiraishi, Ina-shi (JP)

(21) Appl. No.: 18/475,712

(22) Filed: Sep. 27, 2023

(30) Foreign Application Priority Data
Sep. 29, 2022 (JP) 2022-155987

(51) Int. Cl. G01C 19/5628; H03H 3/02; H03H 9/215; H10N 30/082

(52) U.S. Cl. CPC G01C 19/5628; H03H 3/02; H03H 9/215; H10N 30/082; H03H 2003/026

(57) ABSTRACT

A method for manufacturing a vibrator includes a preparation step of preparing a quartz crystal substrate having a first surface and a second surface that are in a front and back relationship, a first protective film formation step of forming a first protective film in an element formation region of the first surface, the first protective film having a first opening overlapping a first groove formation region and a second opening overlapping a second groove formation region, in which a region of the quartz crystal substrate where the vibrator is formed is referred to as the element formation region, a region where the first groove is formed is referred to as the first groove formation region, and a region where the second groove is formed is referred to as the second groove formation region, and a first dry etching step of dry etching the quartz crystal substrate from the first surface through the first protective film. Wa<Wb, in which Wa represents a width of the first opening and Wb represents a width of the second opening.

The present application is based on, and claims priority from JP Application Serial Number 2022-155987, filed Sep. 29, 2022, the disclosure of which is hereby incorporated by reference herein in its entirety.

### BACKGROUND

### 1. Technical Field

The present disclosure relates to a method for manufacturing a vibrator.

### 2. Related Art

JP-A-2007-013382 discloses a method for manufacturing a quartz crystal vibrator element including a pair of vibration arms each having a groove on a front surface and a lower surface, in which an outer shape of the quartz crystal vibrator element and the groove of each of the vibration arms are collectively formed by using a micro loading effect of dry etching. The micro loading effect refers to an effect in which, at a dense portion having a small processing width and a sparse portion having a large processing width, a processing depth is larger, that is, an etching rate is larger, in the sparse portion than in the dense portion even when dry etching is performed under the same condition.

However, in JP-A-2007-013382, for example, it is not assumed to form grooves having different depths for a plurality of vibration arms.

### SUMMARY

A method for manufacturing a vibrator according to the present disclosure is a method for manufacturing a vibrator including a first vibration arm that has a first surface and a second surface which are in a front and back relationship and that has a bottomed first groove opened in the first surface, and a second vibration arm that has a bottomed second groove opened in the first surface. The method includes: a preparation step of preparing a quartz crystal substrate having the first surface and the second surface; a first protective film formation step of forming a first protective film in an element formation region of the first surface, the first protective film having a first opening overlapping a first groove formation region and a second opening overlapping a second groove formation region, in which a region of the quartz crystal substrate where the vibrator is formed is referred to as the element formation region, a region where the first groove is formed is referred to as the first groove formation region, and a region where the second groove is formed is referred to as the second groove formation region; and a first dry etching step of dry etching the quartz crystal substrate from the first surface through the first protective film. Wa<Wb, in which Wa represents a width of the first opening and Wb represents a width of the second opening.

A method for manufacturing a vibrator according to the present disclosure is a method for manufacturing a vibrator including a first vibration arm that has a first surface and a second surface which are in a front and back relationship and that has a bottomed first groove opened in the first surface, and a second vibration arm that has a bottomed second groove opened in the first surface. The method includes: a preparation step of preparing a quartz crystal substrate having the first surface and the second surface; a first protective film formation step of forming a first protective film in an element formation region of the first surface, the first protective film having a first opening overlapping a first groove formation region, a first rate adjustment portion located in the first opening, and a second opening overlapping a second groove formation region, in which a region of the quartz crystal substrate where the vibrator is formed is referred to as the element formation region, a region where the first groove is formed is referred to as the first groove formation region, and a region where the second groove is formed is referred to as the second groove formation region; and a first dry etching step of dry etching the quartz crystal substrate from the first surface through the first protective film. Da<Wb, in which Da represents a separation distance between an edge of the first opening and the first rate adjustment portion and Wb represents a width of the second opening.

### BRIEF DESCRIPTION OF THE DRAWINGS

FIG. 1 is a plan view showing a vibrator according to a first embodiment.

FIG. 2 is a cross-sectional view taken along a line A-A in FIG. 1.

FIG. 3 is a cross-sectional view taken along a line B-B in FIG. 1.

FIG. 4 is a schematic diagram showing a drive state of the vibrator.

FIG. 5 is a schematic diagram showing a drive state of the vibrator.

FIG. 6 is a graph showing a relationship between d1, d2 and sensitivity when d1=d2.

FIG. 7 is a graph showing a relationship between d2/d1 and sensitivity.

FIG. 8 is a flowchart showing a method for manufacturing the vibrator.

FIG. 9 is a cross-sectional view showing the method for manufacturing the vibrator.

FIG. 10 is a cross-sectional view showing the method for manufacturing the vibrator.

FIG. 11 is a cross-sectional view showing the method for manufacturing the vibrator.

FIG. 12 is a cross-sectional view showing the method for manufacturing the vibrator.

FIG. 13 is a cross-sectional view showing the method for manufacturing the vibrator.

FIG. 14 is a cross-sectional view showing the method for manufacturing the vibrator.

FIG. 15 is a cross-sectional view showing a vibrator according to a second embodiment.

FIG. 16 is a cross-sectional view showing the vibrator according to the second embodiment.

FIG. 17 is a cross-sectional view showing a method for manufacturing the vibrator.

FIG. 18 is a cross-sectional view showing the method for manufacturing the vibrator.

FIG. 19 is a cross-sectional view showing the method for manufacturing the vibrator.

FIG. 20 is a cross-sectional view showing the method for manufacturing the vibrator.

FIG. 21 is a cross-sectional view showing a vibrator according to a third embodiment.

FIG. 22 is a cross-sectional view showing the vibrator according to the third embodiment.

FIG. 23 is a cross-sectional view showing a method for manufacturing the vibrator.

FIG. 24 is a plan view showing a first protective film.

FIG. 25 is a cross-sectional view showing the method for manufacturing the vibrator.

FIG. 26 is a cross-sectional view showing the method for manufacturing the vibrator.

FIG. 27 is a cross-sectional view showing the method for manufacturing the vibrator.

FIG. 28 is a plan view showing a second protective film.

FIG. 29 is a cross-sectional view showing the method for manufacturing the vibrator.

FIG. 30 is a plan view showing a vibrator according to a fourth embodiment.

FIG. 31 is a cross-sectional view showing a vibrator according to a modification.

FIG. 32 is a cross-sectional view showing the vibrator according to the modification.

### DESCRIPTION OF EMBODIMENTS

Hereinafter, a method for manufacturing a vibrator according to the present disclosure will be described in detail based on embodiments illustrated with reference to the accompanying drawings.

### First Embodiment

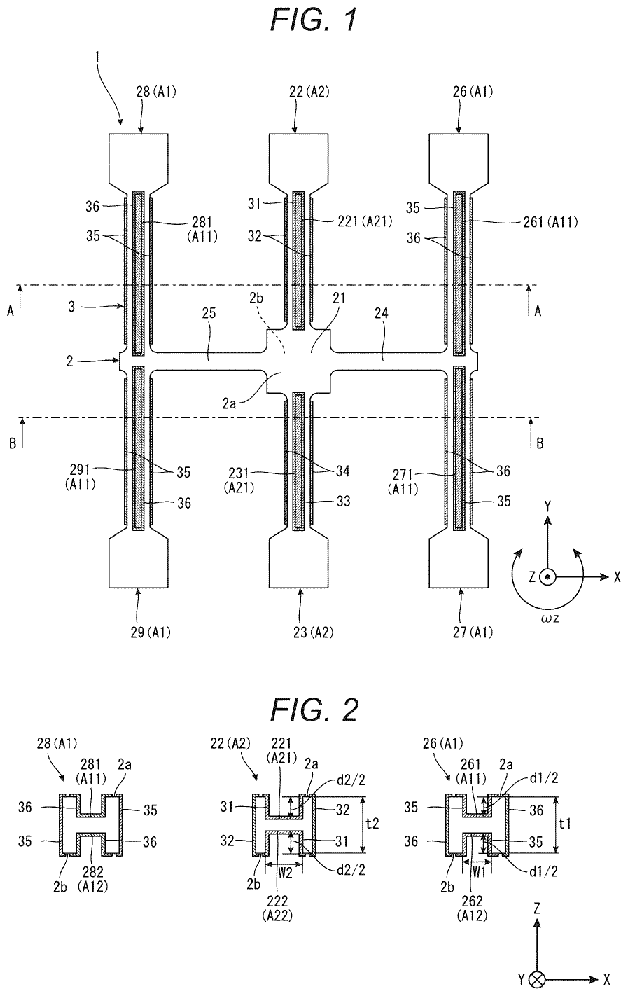

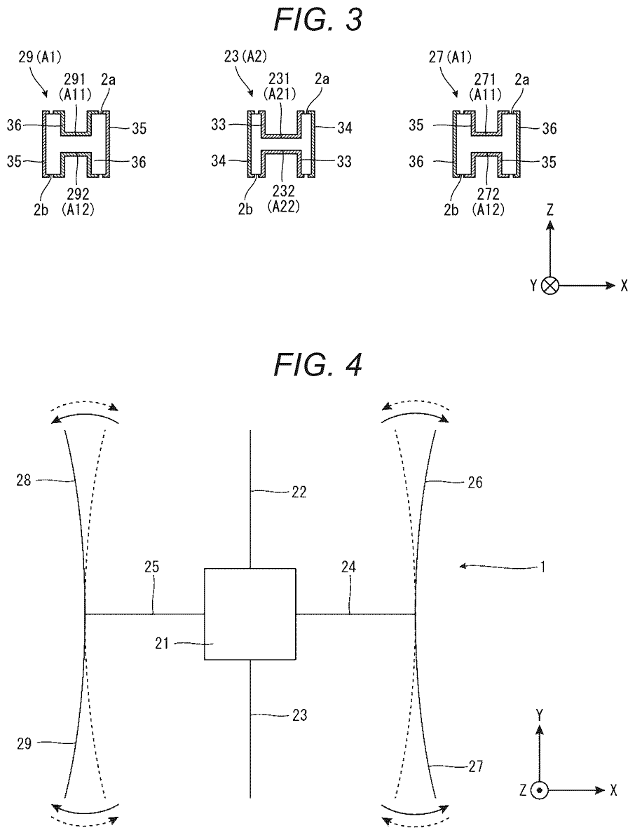

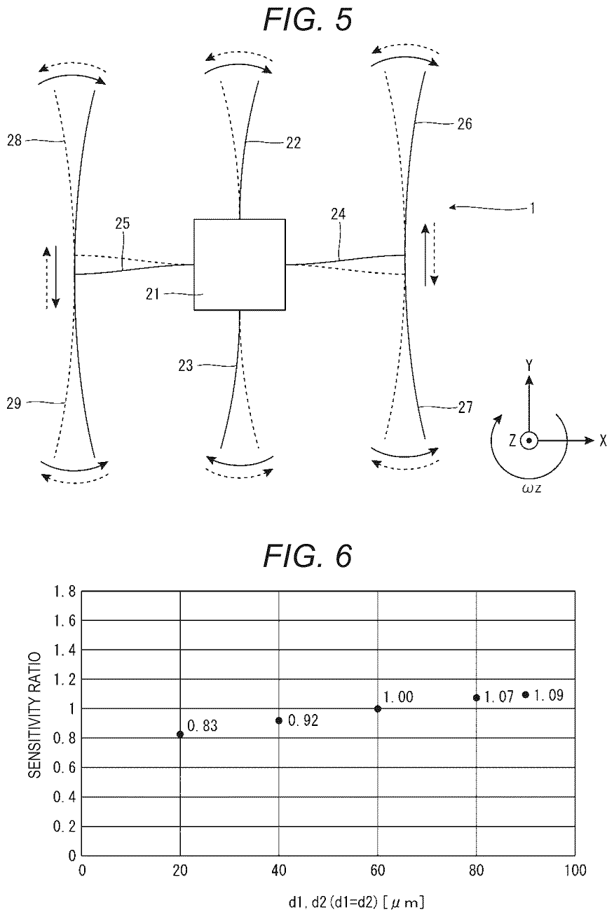

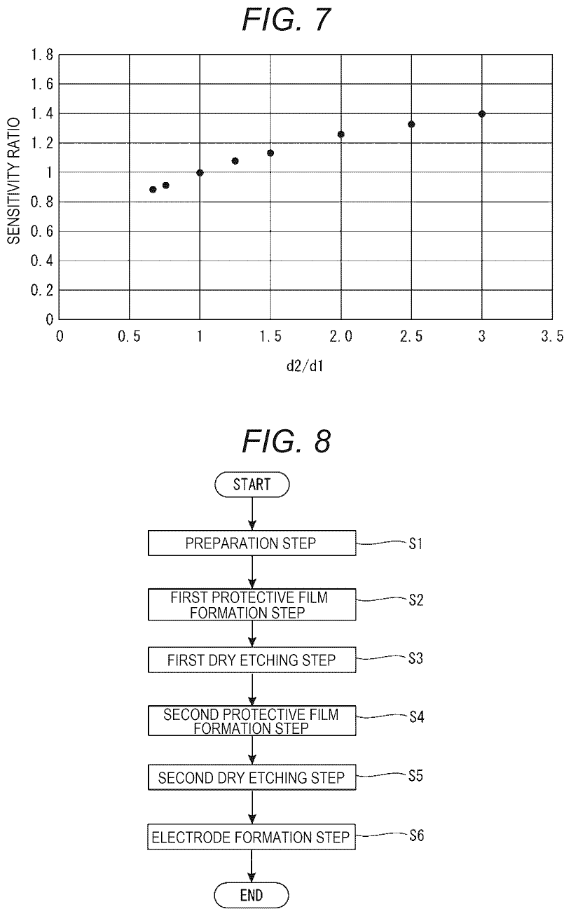

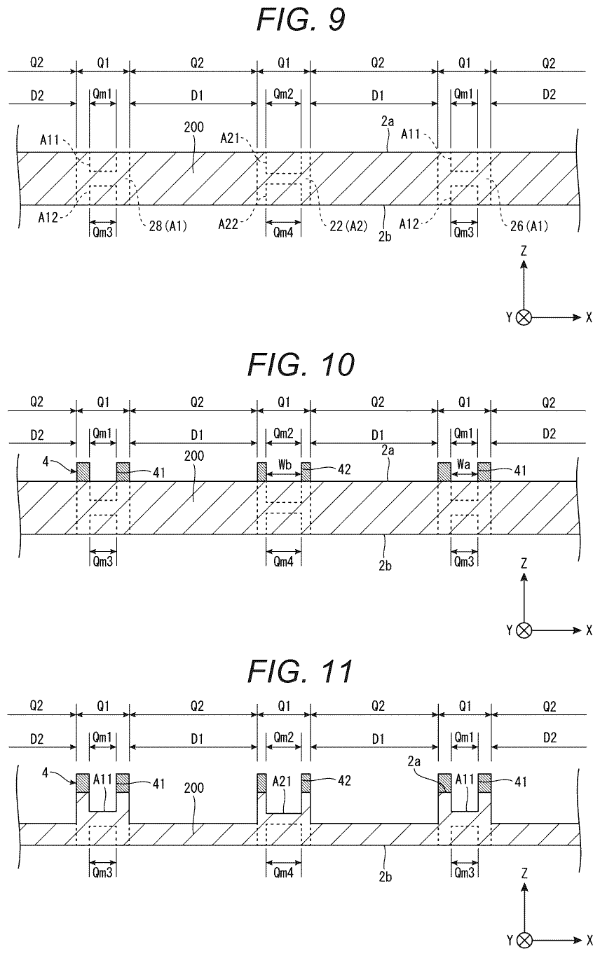

FIG. 1 is a plan view showing a vibrator according to a first embodiment. FIG. 2 is a cross-sectional view taken along a line A-A in FIG. 1. FIG. 3 is a cross-sectional view taken along a line B-B in FIG. 1. FIGS. 4 and 5 are schematic diagrams showing drive states of the vibrator. FIG. 6 is a graph showing a relationship between d1, d2 and sensitivity when d1=d2. FIG. 7 is a graph showing a relationship between d2/d1 and sensitivity. FIG. 8 is a flowchart showing a method for manufacturing the vibrator. FIGS. 9 to 14 are cross-sectional views showing the method for manufacturing the vibrator.

Hereinafter, an X-axis, a Y-axis, and a Z-axis which are three axes orthogonal to one another are shown for the convenience of description. A direction along the X-axis is also referred to as an X-axis direction, a direction along the Y-axis is also referred to as a Y-axis direction, and a direction along the Z-axis is also referred to as a Z-axis direction. An arrow side of each axis is also referred to a “positive side”, and an opposite side is also referred to a “negative side”. A positive side in the Z-axis direction is also referred to as “up”, and a negative side in the Z-axis direction is also referred to as “down”. A plan view from the Z-axis direction is also simply referred to as a “plan view”.

First, a vibrator 1 manufactured using a method for manufacturing a vibrator according to the embodiment will be described. The vibrator 1 is an angular velocity detection element capable of detecting an angular velocity ωz around the Z-axis. As shown in FIGS. 1 to 3, the vibrator 1 includes a vibration substrate 2 formed by patterning a Z-cut quartz crystal substrate, and an electrode 3 deposited on a surface of the vibration substrate 2.

The vibration substrate 2 has a thickness in the Z-axis direction, has a plate shape extending in an X-Y plane, and has an upper surface 2a serving as a first surface and a lower surface 2b serving as a second surface which are in a front and back relationship. The vibration substrate 2 includes a base portion 21 located in a center portion of the vibration substrate 2, a pair of detection vibration arms 22 and 23 serving as a second vibration arm A2 extending from the base portion 21 to both sides in the Y-axis direction, a pair of support arms 24 and 25 extending from the base portion 21 to both sides in the X-axis direction, a pair of drive vibration arms 26 and 27 serving as a first vibration arm A1 extending from a tip end portion of the support arm 24 to both sides in the Y-axis direction, and a pair of drive vibration arms 28 and 29 serving as the first vibration arm A1 extending from a tip end portion of the support arm 25 to both sides in the Y-axis direction. The base portion 21 is supported by a support member (not shown).

According to the vibrator 1 having such a shape, as will be described later, since the drive vibration arms 26, 27, 28, and 29 perform flexural vibrations in a balanced manner in a drive vibration mode, an unnecessary vibration is less likely to occur in the detection vibration arms 22 and 23, and the angular velocity ωz can be accurately detected.

The detection vibration arm 22 has a bottomed groove 221 serving as a second groove A21 formed in the upper surface 2a and a bottomed groove 222 serving as a fourth groove A22 formed in the lower surface 2b. The grooves 221 and 222 are formed along the detection vibration arm 22. The grooves 221 and 222 are formed symmetrically.

The detection vibration arm 23 has a bottomed groove 231 serving as the second groove A21 formed in the upper surface 2a and a bottomed groove 232 serving as the fourth groove A22 formed in the lower surface 2b. The grooves 231 and 232 are formed along the detection vibration arm 23. The grooves 231 and 232 are formed symmetrically.

The two detection vibration arms 22 and 23 are designed to have the same configuration (shape and dimension).

The drive vibration arm 26 has a bottomed groove 261 as a first groove A11 formed in the upper surface 2a and a bottomed groove 262 serving as a third groove A12 formed in the lower surface 2b. The grooves 261 and 262 are formed along the drive vibration arm 26. The grooves 261 and 262 are formed symmetrically.

The drive vibration arm 27 has a bottomed groove 271 serving as the first groove A11 formed in the upper surface 2a and a bottomed groove 272 serving as the third groove A12 formed in the lower surface 2b. The grooves 271 and 272 are formed along the drive vibration arm 27. The grooves 271 and 272 are formed symmetrically.

The drive vibration arm 28 has a bottomed groove 281 serving as the first groove A11 formed in the upper surface 2a and a bottomed groove 282 serving as the third groove A12 formed in the lower surface 2b. The grooves 281 and 282 are formed along the drive vibration arm 28. The grooves 281 and 282 are formed symmetrically.

The drive vibration arm 29 has a bottomed groove 291 serving as the first groove A11 formed in the upper surface 2a and a bottomed groove 292 serving as the third groove A12 formed in the lower surface 2b. The grooves 291 and 292 are formed along the drive vibration arm 29. The grooves 291 and 292 are formed symmetrically.

The four drive vibration arms 26, 27, 28, and 29 are designed to have the same configuration (shape and dimension). A width W1 of each of the grooves 261, 262, 271, 272, 281, 282, 291, and 292 formed in the respective drive vibration arms 26, 27, 28, and 29 is smaller than a width W2 of each of the grooves 221, 222, 231, and 232 formed in the respective detection vibration arms 22 and 23. That is, W1<W2.

The electrode 3 includes a first detection signal electrode 31, a first detection ground electrode 32, a second detection signal electrode 33, a second detection ground electrode 34, a drive signal electrode 35, and a drive ground electrode 36. The first detection signal electrode 31 is disposed on the upper surface 2a and the lower surface 2b of the detection vibration arm 22, and the first detection ground electrode 32 is disposed on both side surfaces of the detection vibration arm 22. The second detection signal electrode 33 is disposed on the upper surface 2a and the lower surface 2b of the detection vibration arm 23, and the second detection ground electrode 34 is disposed on both side surfaces of the detection vibration arm 23. The drive signal electrode 35 is disposed on the upper surfaces 2a and the lower surfaces 2b of each of the drive vibration arms 26 and 27 and on both side surfaces of each of the drive vibration arms 28 and 29. The drive ground electrode 36 is disposed on both side surfaces of each of the drive vibration arms 26 and 27 and on the upper surface 2a and the lower surface 2b of each of the drive vibration arms 28 and 29.

The configuration of the vibrator 1 is briefly described above. The vibrator 1 having such a configuration detects the angular velocity ωz around the Z-axis as follows.

When a drive signal is applied between the drive signal electrode 35 and the drive ground electrode 36, as shown in FIG. 4, the drive vibration arms 26 and 27 and the drive vibration arms 28 and 29 perform flexural vibrations in opposite phases in the X-axis direction (hereinafter, this state is also referred to as a “drive vibration mode”). In this state, vibrations of the drive vibration arms 26, 27, 28, and 29 are in balance, and the detection vibration arms 22 and 23 do not vibrate. When an angular velocity ωz is applied to the vibrator 1 in a state where the vibrator 1 is driven in the drive vibration mode, as shown in FIG. 5, a Coriolis force acts on the drive vibration arms 26, 27, 28, and 29 to excite a flexural vibration in the Y-axis direction, and the detection vibration arms 22 and 23 perform a flexural vibration in the X-axis direction in response to the excited flexural vibration (hereinafter, this state is also referred to as a “detection vibration mode”).

Electric charges generated in the detection vibration arm 22 due to such a flexural vibration are read out as a first detection signal from the first detection signal electrode 31, electric charges generated in the detection vibration arms 23 are read out as a second detection signal from the second detection signal electrode 33, and the angular velocity ωz is calculated based on the first and second detection signals. Since the first and second detection signals have opposite phases, the angular velocity ωz can be detected more accurately by using a differential detection method.

Next, a relationship between the grooves formed in the detection vibration arms 22 and 23 and the grooves formed in the drive vibration arms 26, 27, 28, and 29 will be described. As described above, the detection vibration arms 22 and 23 have the same configuration, and the drive vibration arms 26, 27, 28, and 29 have the same configuration. Hereinafter, for the convenience of description, the detection vibration arms 22 and 23 are collectively referred to as the second vibration arm A2, and the drive vibration arms 26, 27, 28, and 29 are collectively referred to as the first vibration arm A1.

As described above, the first vibration arm A1 has the first groove A11 formed in the upper surface 2a and the third groove A12 formed in the lower surface 2b. The second vibration arm A2 has the second groove A21 formed in the upper surface 2a and the fourth groove A22 formed in the lower surface 2b. Therefore, a cross-sectional shape of each of the first vibration arm A1 and the second vibration arm A2 is an H shape. According to such a configuration, it is possible to increase a length of a heat transfer path during the flexural vibration of the first and second vibration arms A1 and A2, a thermoelastic loss is reduced, and a Q value is increased. Further, the first and second vibration arms A1 and A2 are soft, and are easily flexed and deformed in the X-axis direction. Therefore, an amplitude of the first vibration arm A1 in the drive vibration mode can be increased. As the amplitude of the first vibration arm A1 increases, the Coriolis force increases, and an amplitude of the second vibration arm A2 in the detection vibration mode increases. Therefore, a large detection signal is obtained, and detection sensitivity of the angular velocity ωz is increased.

Hereinafter, as shown in FIG. 2, a relationship between d2/t2 and d1/t1 will be described in detail, in which t1 is a thickness of the first vibration arm A1, d1 is a depth of the first and third grooves A11 and A12 of the first vibration arm A1, t2 is a thickness of the second vibration arm A2, and d2 is a depth of the second and fourth grooves A21 and A22. d1 is a total depth of the first and third grooves A11 and A12. In the embodiment, since the first and third grooves A11 and A12 are formed symmetrically, a depth of each of the first and third grooves A11 and A12 is d1/2. Similarly, d2 is a total depth of the second and fourth grooves A21 and A22. In the embodiment, since the second and fourth grooves A21 and A22 are formed symmetrically, a depth of each of the second and fourth grooves A21 and A22 is d2/2.

FIG. 6 shows a relationship between d1, d2 (d1=d2) and detection sensitivity (sensitivity) of the angular velocity ωz. A plate thickness of the vibration substrate 2, that is, t1 and t2 are 100 μm. The detection sensitivity is represented by a ratio by setting the detection sensitivity when d1 and d2 are 60 μm to 1. As can be seen from the figure, the detection sensitivity increases as d1 and d2 become larger. When d1 and d2 are 90 μm (90% of the plate thickness), the detection sensitivity is only 1.09 times higher than the detection sensitivity when d1 and d2 are 60 μm (60% of the plate thickness). Therefore, it can be seen that when d1=d2, it is difficult to increase the detection sensitivity even when d1 and d2 are increased.

FIG. 7 shows a relationship between d2/d1 and the detection sensitivity. A plate thickness of the vibration substrate 2, that is, t1 and t2 are 100 μm. The detection sensitivity is represented by a ratio by setting the detection sensitivity when d2/d1=1 in a configuration in the related art to 1. As can be seen from the figure, the detection sensitivity increases as d2/d1 increases. That is, the deeper the second and fourth grooves A21 and A22 of the second vibration arm A2 relative to the first and third grooves A11 and A12 of the first vibration arm A1, the higher the detection sensitivity. It can be seen that the detection sensitivity can be increased as compared with a configuration in the related art in a region of d2/d1>1.

Accordingly, in the vibrator 1, d2/d1>1, that is, d2/t2>d1/t1. That is, the first and third grooves A11 and A12 are shallower than the second and fourth grooves A21 and A22. Accordingly, the detection sensitivity can be increased as compared with the configuration in the related art, and the detection sensitivity that cannot be achieved in the configuration in the related art can be obtained.

The overall configuration of the vibrator 1 is described above. Next, a method for manufacturing the vibrator 1 will be described. Here, the drive vibration arms 26, 27, 28, and 29 are also collectively referred to as the first vibration arm A1, and the detection vibration arms 22 and 23 are also collectively referred to as the second vibration arm A2. As shown in FIG. 8, the method for manufacturing the vibrator 1 includes a preparation step S1, a first protective film formation step S2, a first dry etching step S3, a second protective film formation step S4, a second dry etching step S5, and an electrode formation step S6. Hereinafter, the steps S1 to S6 will be described in order using a cross-sectional view corresponding to the view shown in FIG. 2.

### Preparation Step S1

First, as shown in FIG. 9, a Z-cut quartz crystal substrate 200 which is a base material of the vibration substrate 2 is prepared. The quartz crystal substrate 200 has the upper surface 2a serving as a first surface and the lower surface 2b serving as a second surface which are in a front and back relationship. The quartz crystal substrate 200 is larger than the vibration substrate 2, and a plurality of vibration substrates 2 can be formed from the quartz crystal substrate 200. A quartz crystal wafer obtained by Z-cutting a lumbered synthetic quartz crystal can be used as the quartz crystal substrate 200.

Hereinafter, a region where the vibration substrate 2 is formed is referred to as an element formation region Q1, a region other than the element formation region Q1 is referred to as a removal region Q2, a region where the first groove A11 is formed is referred to as a first groove formation region Qm1, a region where the second groove A21 is formed is referred to as a second groove formation region Qm2, a region where the third groove A12 is formed is referred to as a third groove formation region Qm3, and a region where the fourth groove A22 is formed is referred to as a fourth groove formation region Qm4. Although not shown, a plurality of element formation regions Q1 are provided in a matrix in one quartz crystal substrate 200.

Next, if necessary, both surfaces of the quartz crystal substrate 200 are polished for thickness adjustment and planarization. Such polishing is also referred to as lapping. For example, a wafer polishing device including a pair of upper and lower surface plates is used, the quartz crystal substrate 200 is interposed between the surface plates that rotate in opposite directions, and both surfaces of the quartz crystal substrate 200 are polished while the quartz crystal substrate 200 is rotated and a polishing liquid is supplied. In the polishing, mirror polishing may be performed on both surfaces of the quartz crystal substrate 200 as necessary following the lapping described above. Such polishing is also referred to polishing processing. Accordingly, both surfaces of the quartz crystal substrate 200 can be mirror-finished.

### First Protective Film Formation Step S2

Next, as shown in FIG. 10, a first protective film 4 is formed on the upper surface 2a of the quartz crystal substrate 200. The first protective film 4 is formed on the element formation region Q1 and has a first opening 41 overlapping the first groove formation region Qm1 and a second opening 42 overlapping the second groove formation region Qm2. A width Wa of the first opening 41 is smaller than a width Wb of the second opening 42. That is, Wa<Wb. The widths Wa and Wb refer to lengths in the X-axis direction orthogonal to an extending direction of the first and second vibration arms A1 and A2. The widths Wa and Wb are designed to be sufficiently small in order to exhibit the micro loading effect, and for example, are 100 μm or less. The widths Wa and Wb are appropriately set in accordance with a required etching depth.

The removal region Q2, specifically, a distance D1 between adjacent vibration arms and a distance D2 between adjacent elements are designed to be sufficiently larger than the width Wa and the width Wb.

A material and a formation method of the first protective film 4 are not particularly limited. For example, the first protective film 4 may be a metal film made of a metal material. In this case, the first protective film 4 can be obtained by forming a metal film serving as a base material of the first protective film 4 on the upper surface of the quartz crystal substrate 200 using various film formation methods such as sputtering, vapor deposition, and plating, and by patterning the formed metal film using a photolithography technique and an etching technique. When the first protective film 4 is a metal film, the first protective film 4 having a low etching rate can be obtained, and the first protective film 4 can be thinned accordingly. By thinning the first protective film 4, patterning accuracy of the quartz crystal substrate 200 is improved, and an outer shape of the vibration substrate 2 and dimension accuracy of the first and second grooves A11 and A21 are improved.

For example, the first protective film 4 may be a resin film made of a resin material. In this case, the first protective film 4 can be obtained by forming a photoresist serving as a base material of the first protective film 4 on the upper surface of the quartz crystal substrate 200 using various film formation methods such as a spin coating method and a spray coating method, and by patterning the formed photoresist using a photolithography technique. When the first protective film 4 is a resin film, the photoresist can be directly used as the first protective film 4. Therefore, the first protective film formation step S2 can be simplified.

### First Dry Etching Step S3

Next, as shown in FIG. 11, the quartz crystal substrate 200 is dry-etched from the upper surface 2a through the first protective film 4. Since the dry etching can be performed without being affected by a crystal plane of quartz crystal, good dimension accuracy can be obtained. Dry etching is reactive ion etching and is performed using a reactive ion etching (RIE) device. A reactive gas introduced into the RIE device is not particularly limited, and for example, SF₆, CF₄, C₂F₄, C₂F₆, C₃F₆, or C₄F₈ can be used.

In this step, the quartz crystal substrate 200 is dry-etched by using a micro loading effect. The “micro loading effect” refers to an effect in which, at a dense portion having a small processing width and a sparse portion having a large processing width, a processing depth is larger, that is, an etching rate is larger, in the sparse portion than in the dense portion even when dry etching is performed under the same condition. In the embodiment, as described above, the width Wa of the first opening 41 is smaller than the width Wb of the second opening 42, and the removal region Q2 is larger than the widths Wa and Wb. Accordingly, among the first groove formation region Qm1, the second groove formation region Qm2, and the removal region Q2 which are three regions to be etched, the removal region Q2 is the sparsest portion, and the first groove formation region Qm1 is the densest portion. Therefore, an etching rate in this step is the removal region Q2>the second groove formation region Qm2>the first groove formation region Qm1 according to the micro loading effect.

Therefore, as shown in FIG. 11, an etching depth of the removal region Q2 is the largest, an etching depth of the second groove formation region Qm2 is large, and an etching depth of the first groove formation region Qm1 is the smallest in this step. Accordingly, in this step, the first groove A11 and the second groove A21 having different depths are collectively formed. Therefore, the first groove A11 and the second groove A21 are easily formed. At the end of this step, the etching depth of the removal region Q2 reaches half or more of a thickness of the quartz crystal substrate 200.

As described above, the step of etching the quartz crystal substrate 200 from the upper surface 2a is completed. Subsequent steps S4 and S5 are steps of etching the quartz crystal substrate 200 from the lower surface 2b, and are similar to the above-described steps S2 and S3. Therefore, description of contents overlapping the steps S2 and S3 will be omitted.

### Second Protective Film Formation Step S4

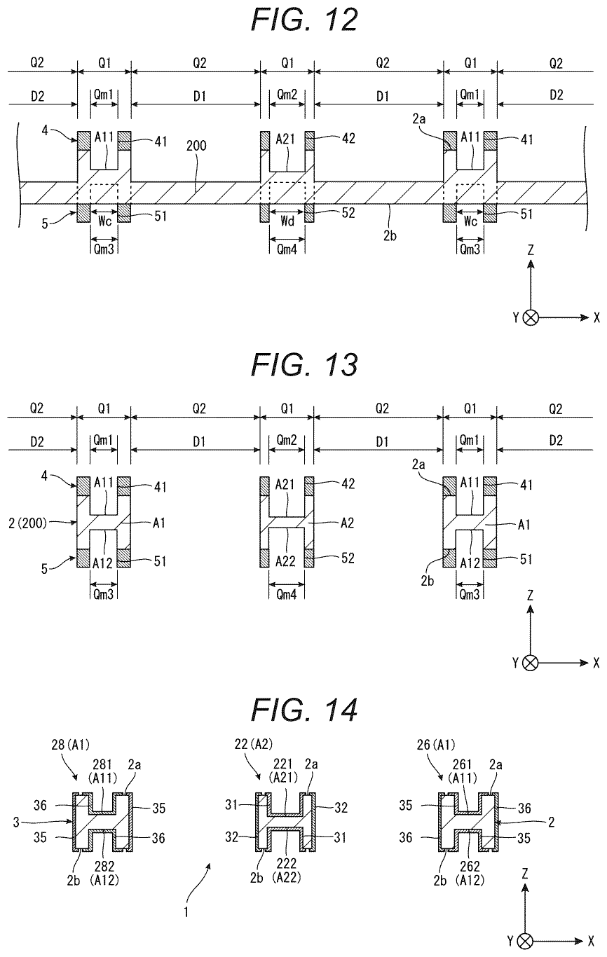

Next, as shown in FIG. 12, a second protective film 5 is formed on the lower surface 2b of the quartz crystal substrate 200. The second protective film 5 is formed on the element formation region Q1 and has a third opening 51 overlapping the third groove formation region Qm3 and a fourth opening 52 overlapping the fourth groove formation region Qm4. A width Wc of the third opening 51 is smaller than a width Wd of the fourth opening 52. That is, Wc<Wd. The widths Wc and Wd refer to lengths in the X-axis direction orthogonal to the extending direction of the first and second vibration arms A1 and A2. The widths Wc and Wd are designed to be sufficiently small in order to exhibit the micro loading effect. The widths Wc and Wd are appropriately set in accordance with a required etching depth. The second protective film 5 has the same structure as the first protective film 4.

The removal region Q2, specifically, the distance D1 between adjacent vibration arms and the distance D2 between adjacent elements are designed to be sufficiently larger than the width Wc and the width Wd.

### Second Dry Etching Step S5

Next, as shown in FIG. 13, the quartz crystal substrate 200 is dry-etched from the lower surface 2b through the second protective film 5. As described above, the width Wc of the third opening 51 is smaller than the width Wd of the fourth opening 52, and the removal region Q2 is larger than the widths Wc and Wd. Accordingly, among the third groove formation region Qm3, the fourth groove formation region Qm4, and the removal region Q2 which are three regions to be etched, the removal region Q2 is the sparsest portion, and the third groove formation region Qm3 is the densest portion. Therefore, an etching rate in this step is the removal region Q2>the fourth groove formation region Qm4>the third groove formation region Qm3 according to the micro loading effect.

Therefore, as shown in FIG. 13, an etching depth of the removal region Q2 is the largest, an etching depth of the fourth groove formation region Qm4 is large, and an etching depth of the third groove formation region Qm3 is the smallest in this step. Accordingly, in this step, the third groove A12 and the fourth groove A22 having different depths are collectively formed. Therefore, the third groove A12 and the fourth groove A22 are easily formed. At the end of this step, the quartz crystal substrate 200 is etched through in the removal region Q2, and an outer shape of the vibration substrate 2 is finished. Accordingly, a further dry etching step for finishing the outer shape of the vibration substrate 2 is not necessary, and thus the number of manufacturing steps of the vibrator 1 can be reduced and the cost of the vibrator 1 can be reduced.

A plurality of vibration substrates 2 are obtained from the quartz crystal substrate 200 by performing the above steps.

### Electrode Formation Step S6

Next, as shown in FIG. 14, the electrode 3 is formed on a surface of the vibration substrate 2. A method for forming the electrode 3 is not particularly limited, and for example, the electrode 3 can be obtained by forming a metal film on the surface of the vibration substrate 2 and patterning the metal film using a photolithography technique and an etching technique.

The vibrator 1 is obtained by performing the above steps. According to such a manufacturing method, the first groove A11 and the second groove A21 having different depths can be collectively formed by using the micro loading effect. Similarly, the third groove A12 and the fourth groove A22 having different depths can be easily formed collectively by using the micro loading effect. A positional deviation of the grooves A11, A21, A12, and A22 relative to the outer shape of the vibration substrate 2 is prevented, and formation accuracy of the vibration substrate 2 is improved.

In the embodiment, the removal region Q2 of the quartz crystal substrate 200 is not etched through until the second dry etching step S5, and a mechanical strength of the quartz crystal substrate 200 can be maintained sufficiently high. That is, steps up to the second dry etching step S5 that is a final stage can be performed in a state in which the mechanical strength of the quartz crystal substrate 200 remains high. Therefore, handleability is improved, and the vibrator 1 is easily manufactured.

The present disclosure is not limited thereto, and for example, the removal region Q2 of the quartz crystal substrate 200 may be etched through in the first dry etching step S3. That is, in the first dry etching step S3, the outer shape of the vibration substrate 2 may be finished. In this manner, since the outer shape of the vibration substrate 2 is formed by dry etching from the upper surface 2a, the first protective film 4 can be continuously used until the outer shape is finished. Therefore, the outer shape can be formed with high accuracy. Accordingly, unnecessary vibrations of the first and second vibration arms A1 and A2 and a decrease in vibration balance are prevented, and the vibrator 1 having excellent angular velocity detection characteristics can be manufactured.

The method for manufacturing the vibrator is described above. As described above, the method for manufacturing such a vibrator is a method for manufacturing the vibrator 1 including the first vibration arm A1 that has the upper surface 2a serving as the first surface and the lower surface 2b serving as the second surface which are in a front and back relationship and that has the bottomed first groove A11 opened in the upper surface 2a, and the second vibration arm A2 that has the bottomed second groove A21 opened in the upper surface 2a. The method includes: the preparation step S1 of preparing the quartz crystal substrate 200 having the upper surface 2a and the lower surface 2b; a first protective film formation step S2 of forming the first protective film 4 in the element formation region Q1 of the upper surface 2a, the first protective film 4 having the first opening 41 overlapping the first groove formation region Qm1 and the second opening 42 overlapping the second groove formation region Qm2, in which a region of the quartz crystal substrate 200 where the vibrator 1 is formed is referred to as the element formation region Q1, a region where the first groove A11 is formed is referred to as the first groove formation region Qm1, and a region where the second groove A21 is formed is referred to as the second groove formation region Qm2; and a first dry etching step S3 of dry etching the quartz crystal substrate 200 from the upper surface 2a through the first protective film 4. Wa<Wb, in which Wa represents a width of the first opening 41 and Wb represents a width of the second opening 42. Accordingly, an etching rate of the first groove formation region Qm1 can be made lower than an etching rate of the second groove formation region Qm2 according to the micro loading effect. Therefore, the first and second grooves A11 and A21 having different depths can be collectively formed, and the vibrator 1 can be easily manufactured. Since the first and second grooves A11 and A21 are formed together with the outer shape, a positional deviation of the first and second grooves A11 and A21 relative to the outer shape is prevented, and formation accuracy of the vibrator 1 is improved.

As described above, the vibrator 1 includes the third groove A12 opened in the lower surface 2b of the first vibration arm A1 and the fourth groove A22 opened in the lower surface 2b of the second vibration arm A2, and the method for manufacturing the vibrator 1 includes: the second protective film formation step S4 of forming the second protective film 5 in the element formation region Q1 of the lower surface 2b, the second protective film 5 having the third opening 51 overlapping the third groove formation region Qm3 and the fourth opening 52 overlapping the fourth groove formation region Qm4, in which a region of the quartz crystal substrate 200 where the third groove A12 is formed is referred to as the third groove formation region Qm3, and a region where the fourth groove A22 is formed is referred to as the fourth groove formation region Qm4; and the second dry etching step S5 of dry etching the quartz crystal substrate 200 from the lower surface 2b through the second protective film 5. Wc<Wd, in which Wc represents a width of the third opening 51 and Wd represents a width of the fourth opening 52. Accordingly, an etching rate of the third groove formation region Qm3 can be made lower than an etching rate of the fourth groove formation region Qm4 according to the micro loading effect. Therefore, the third and fourth grooves A12 and A22 having different depths can be collectively formed, and the vibrator 1 can be easily manufactured.

As described above, the vibrator 1 is an angular velocity detection element configured to detect an angular velocity, the first vibration arm A1 performs a flexural vibration in response to an applied drive signal, and the second vibration arm A2 performs a flexural vibration in response to an applied angular velocity ωz. That is, the first vibration arm A1 includes the drive vibration arms 26, 27, 28, and 29, and the second vibration arm A2 includes the detection vibration arms 22 and 23. Accordingly, since the first grooves A11 formed in the drive vibration arms 26, 27, 28, and 29 are shallower than the second grooves A21 formed in the detection vibration arms 22 and 23, detection sensitivity of the angular velocity detection element can be improved.

As described above, the vibrator 1 includes the base portion 21, the pair of detection vibration arms 22 and 23 serving as the second vibration arm A2 extending from the base portion 21 to both sides in the Y-axis direction which is the first direction, the pair of support arms 24 and 25 extending from the base portion 21 to both sides in the X-axis direction which is the second direction intersecting the Y-axis direction, the pair of drive vibration arms 26 and 27 serving as the first vibration arm A1 extending from the support arm 24 to both sides in the Y-axis direction, and the pair of drive vibration arms 28 and 29 serving as the first vibration arm A1 extending from the support arm 25 to both sides in the Y-axis direction. According to such a configuration, since the drive vibration arms 26, 27, 28, and 29 perform flexural vibrations in a balanced manner in a drive vibration mode, an unnecessary vibration is less likely to occur in the detection vibration arms 22 and 23, and the angular velocity ωz can be accurately detected.

### Second Embodiment

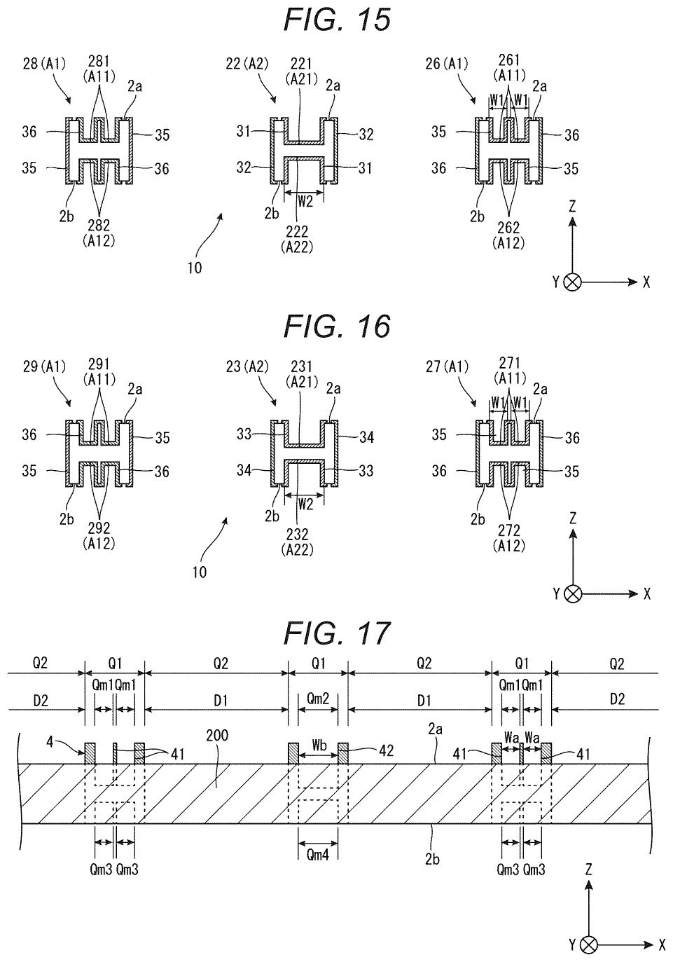

FIGS. 15 and 16 are cross-sectional views showing a vibrator according to a second embodiment. FIGS. 17 to 20 are cross-sectional views showing a method for manufacturing the vibrator.

The method for manufacturing the vibrator according to the embodiment is similar to the method for manufacturing the vibrator according to the first embodiment described above except that a configuration of the vibrator to be manufactured is different. In the following description, the method for manufacturing the vibrator according to the embodiment will be described with a focus on differences from the first embodiment described above, and description of similar matters will be omitted. In the drawings of the embodiment, configurations the same as those of the above embodiment will be denoted by the same reference numerals.

In the method for manufacturing the vibrator according to the embodiment, a vibrator 10 shown in FIGS. 15 and 16 is manufactured. The vibrator 10 is different from the vibrator 1 in a configuration of the first vibration arm A1. In the first vibration arm A1, two first grooves A11 are formed side by side in a width direction of the first vibration arm A1, that is, the X-axis direction. Similarly, two third grooves A12 are formed side by side in the width direction of the first vibration arm A1, that is, the X-axis direction. In this manner, since the two first grooves A11 are formed side by side and the two third grooves A12 are formed side by side, effective widths of the first and third grooves A11 and A12 can be increased as compared with those in the first embodiment described above. Therefore, the Q value of the first vibration arm A1 can be increased, and the first vibration arm A1 can be softened as compared with those in the first embodiment described above. The number of the first grooves A11 is not particularly limited, and may be, for example, three or more. The number of the first grooves A11 can be appropriately set according to the width of the first vibration arm A1, the width W1 of the first groove A11, and the like. The same applies to the third groove A12.

The configuration of the vibrator 10 is described above. Next, a method for manufacturing the vibrator 10 will be described. The method for manufacturing the vibrator 10 is similar to the method for manufacturing the vibrator 1 according to the first embodiment described above, and includes the preparation step S1, the first protective film formation step S2, the first dry etching step S3, the second protective film formation step S4, the second dry etching step S5, and the electrode formation step S6. Hereinafter, the steps S1 to S6 will be described in order, and description of contents the same as those of the first embodiment will be omitted.

### Preparation Step S1

First, the Z-cut quartz crystal substrate 200 which is a base material of the vibration substrate 2 is prepared.

### First Protective Film Formation Step S2

Next, as shown in FIG. 17, the first protective film 4 is formed on the upper surface 2a of the quartz crystal substrate 200. The first protective film 4 is formed on the element formation region Q1 and has two first openings 41 overlapping the first groove formation region Qm1 and the second opening 42 overlapping the second groove formation region Qm2. The width Wa of each of the first openings 41 is smaller than the width Wb of the second opening 42. That is, Wa<Wb.

### First Dry Etching Step S3

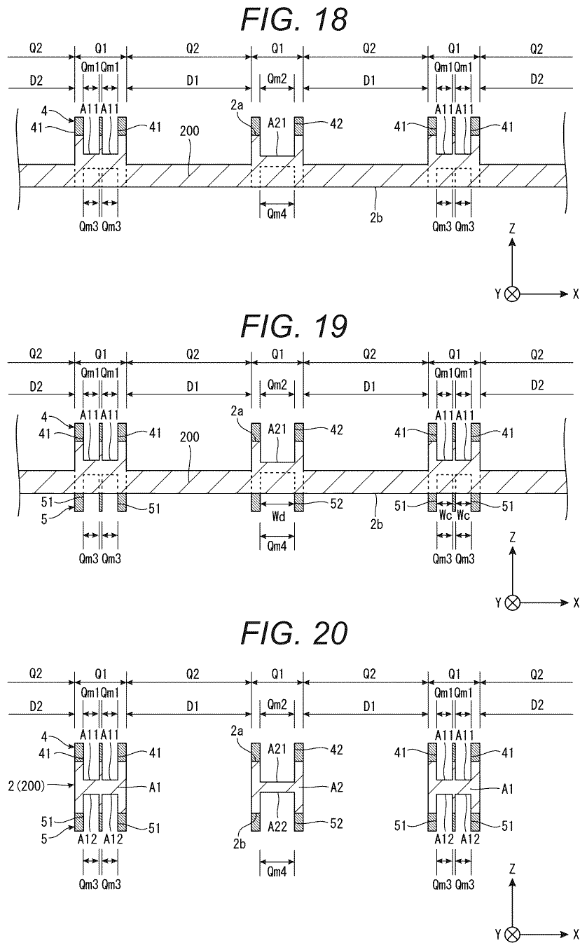

Next, as shown in FIG. 18, the quartz crystal substrate 200 is dry-etched from the upper surface 2a through the first protective film 4. Accordingly, the first grooves A11 and the second groove A21 having different depths are collectively formed by using the micro loading effect.

Second Protective Film formation step S4

Next, as shown in FIG. 19, the second protective film 5 is formed on the lower surface 2b of the quartz crystal substrate 200. The second protective film 5 is formed on the element formation region Q1, and has two third openings 51 overlapping the third groove formation region Qm3, and the fourth opening 52 overlapping the fourth groove formation region Qm4. The width Wc of each of the third openings 51 is smaller than the width Wd of the fourth opening 52. That is, Wc<Wd. The second protective film 5 has the same structure as the first protective film 4.

### Second Dry Etching Step S5

Next, as shown in FIG. 20, the quartz crystal substrate 200 is dry-etched from the lower surface 2b through the second protective film 5. Accordingly, the third grooves A12 and the fourth groove A22 having different depths are collectively formed by using the micro loading effect. A plurality of vibration substrates 2 are obtained from the quartz crystal substrate 200 by performing the above steps.

### Electrode Formation Step S6

Next, the electrode 3 is formed on a surface of the vibration substrate 2. Accordingly, the vibrator 10 is obtained.

As described above, in the method for manufacturing the vibrator according to the embodiment, the first protective film 4 has a plurality of first openings 41 arranged side by side in a direction orthogonal to the extending direction of the first vibration arm A1. Accordingly, a plurality of first grooves A11 can be formed. Therefore, an effective width of the first grooves A11 can be increased as compared with that in the first embodiment. Therefore, the Q value of the first vibration arm A1 can be increased, and the first vibration arm A1 can be softened as compared with those in the first embodiment described above.

The second embodiment as described above can also exhibit the same effect as the first embodiment described above.

### Third Embodiment

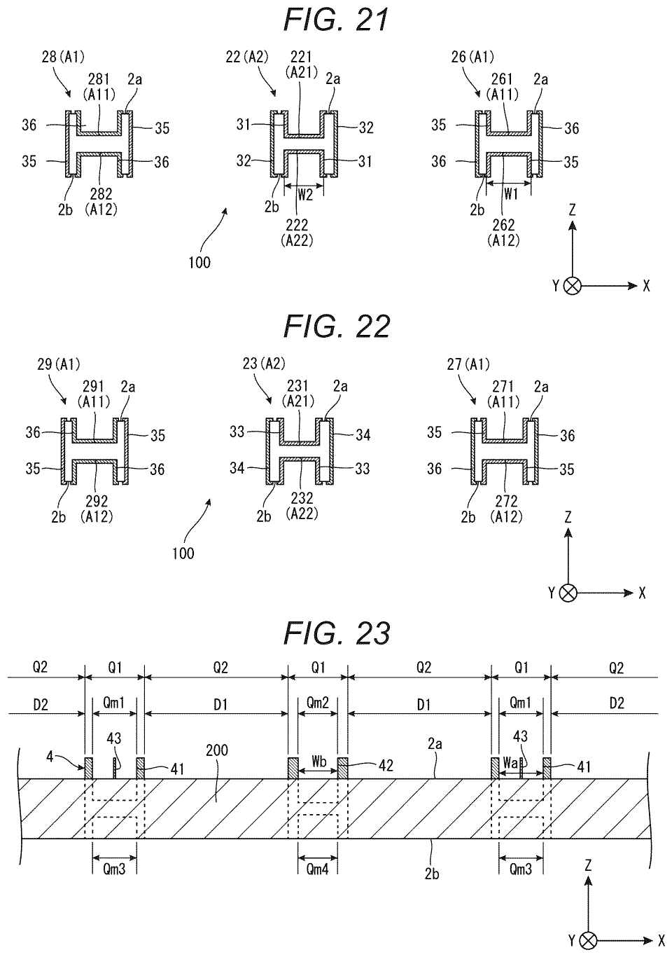

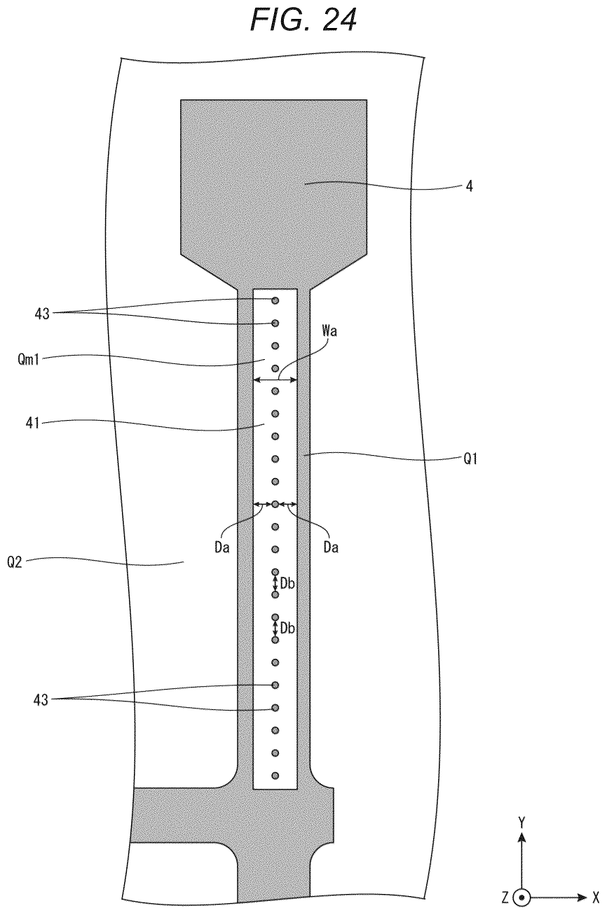

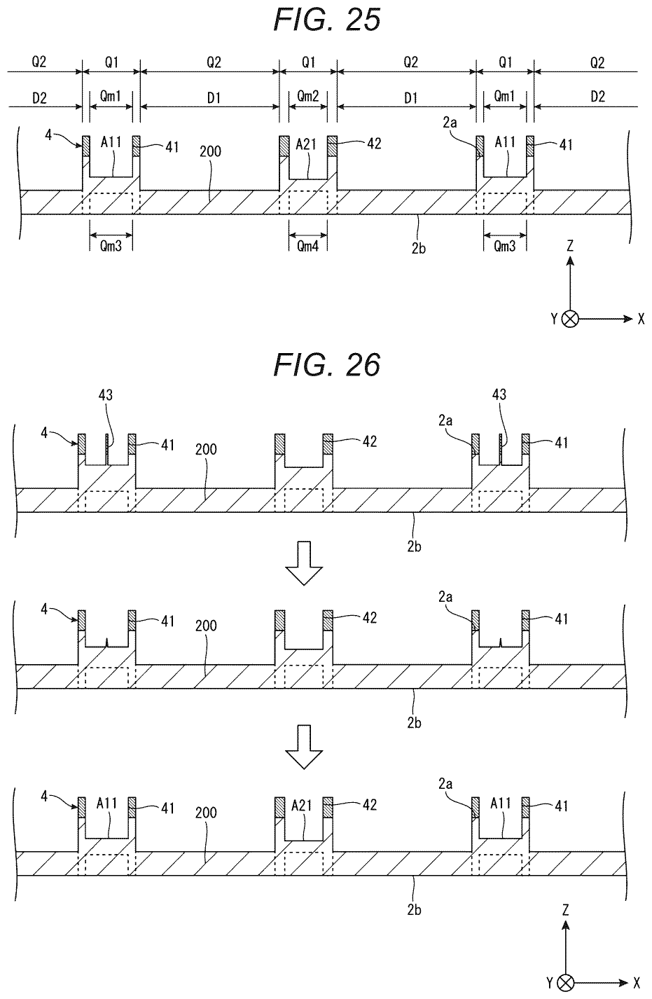

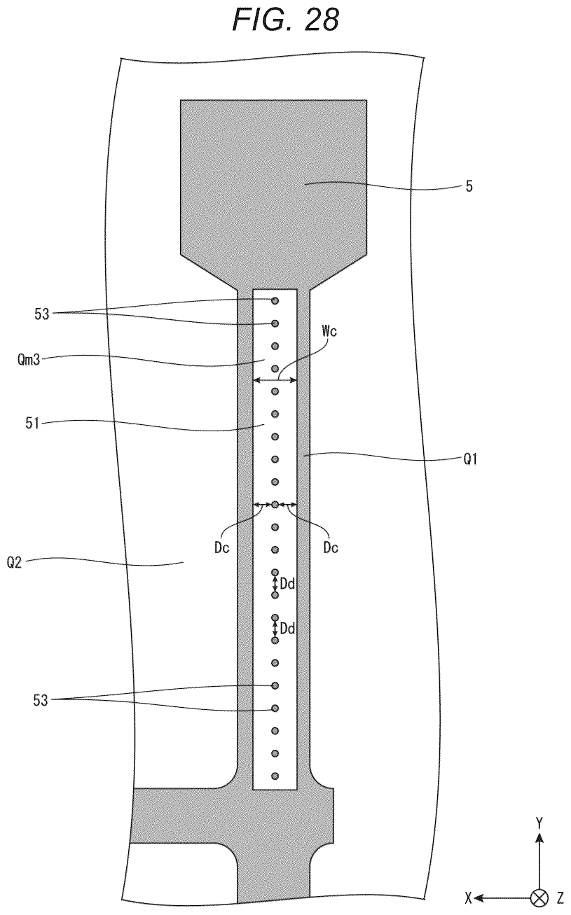

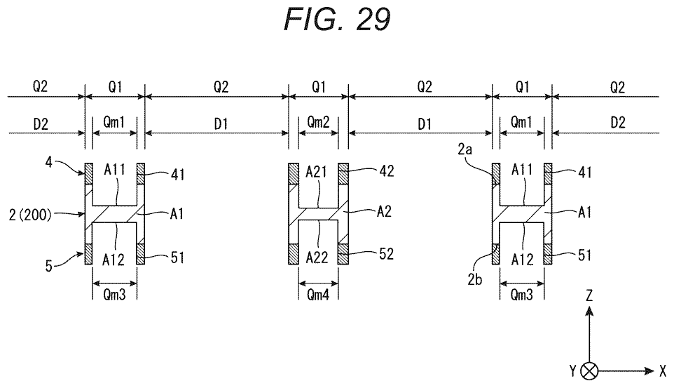

FIGS. 21 and 22 are cross-sectional views showing a vibrator according to a third embodiment. FIG. 23 is a cross-sectional view showing a method for manufacturing the vibrator. FIG. 24 is a plan view showing a first protective film. FIGS. 25 to 27 are cross-sectional views showing the method for manufacturing the vibrator. FIG. 28 is a plan view showing a second protective film. FIG. 29 is a cross-sectional view showing the method for manufacturing the vibrator.

The method for manufacturing the vibrator according to the embodiment is similar to the method for manufacturing the vibrator according to the first embodiment described above except that a configuration of the vibrator to be manufactured is different. In the following description, the method for manufacturing the vibrator according to the embodiment will be described with a focus on differences from the first embodiment described above, and description of similar matters will be omitted. In the drawings of the embodiment, configurations the same as those of the above embodiments will be denoted by the same reference numerals.

In the method for manufacturing the vibrator according to the embodiment, a vibrator 100 shown in FIGS. 21 and 22 is manufactured. The vibrator 100 has the same outer shape as the vibrator 1, and the width W1 of the first and third grooves A11 and A12 is equal to or larger than the width W2 of the second and fourth grooves A21 and A22. That is, W1≥W2. In this manner, since W1≥W2, effective widths of the first and third grooves A11 and A12 can be increased as compared with those in the first and second embodiments described above. Therefore, the Q value of the first vibration arm A1 can be increased, and the first vibration arm A1 can be softened as compared with those in the first and second embodiments described above.

The vibrator 100 is described above. Next, a method for manufacturing the vibrator 100 will be described. The method for manufacturing the vibrator 100 is similar to the method for manufacturing the vibrator 1 according to the first embodiment described above, and includes the preparation step S1, the first protective film formation step S2, the first dry etching step S3, the second protective film formation step S4, the second dry etching step S5, and the electrode formation step S6. Hereinafter, the steps S1 to S6 will be described in order, and description of contents the same as those of the first embodiment will be omitted.

### Preparation Step S1

First, the Z-cut quartz crystal substrate 200 which is a base material of the vibration substrate 2 is prepared.

### First Protective Film Formation Step S2

Next, as shown in FIG. 23, the first protective film 4 is formed on the upper surface 2a of the quartz crystal substrate 200. The first protective film 4 is formed on the element formation region Q1 and has the first opening 41 overlapping the first groove formation region Qm1 and the second opening 42 overlapping the second groove formation region Qm2. The width Wa of the first opening 41 is larger than the width Wb of the second opening 42. That is, Wa>Wb. Therefore, an etching rate of the first groove formation region Qm1 is higher than an etching rate of the second groove formation region Qm2, and the first groove A11 is deeper than the second groove A21 according to the micro loading effect. The first protective film 4 further includes first rate adjustment portions 43 located in the first opening 41. The first rate adjustment portion 43 has a function of reducing the etching rate of the first groove formation region Qm1.

As shown in FIG. 24, a plurality of first rate adjustment portions 43 are located at a center portion in the width direction of the first opening 41, that is, the center portion in the X-axis direction, and are disposed in a manner of being separated from one another along the extending direction of the first vibration arm A1. The first rate adjustment portions 43 are sufficiently small so that the quartz crystal substrate 200 immediately below the first rate adjustment portions 43 is removed in the later first dry etching step S3. Da<Wb, in which Da represents a separation distance between an edge of the first opening 41 and the first rate adjustment portion 43. The separation distance Da refers to a separation distance in the X-axis direction. db<Wb, in which db represents a separation distance between the adjacent first rate adjustment portions 43. Accordingly, the first groove formation region Qm1 is a portion denser than the second groove formation region Qm2, and even when Wa>Wb, an etching rate of the first groove formation region Qm1 can be made lower than an etching rate of the second groove formation region Qm2.

A configuration of the first rate adjustment portion 43 is not particularly limited. For example, one or more elongated first rate adjustment portions 43 extending along the extending direction of the first vibration arm A1 may be provided. Alternatively, a plurality of first rate adjustment portions 43 aligned along the extending direction of the first vibration arm A1 may be arranged in a plurality of rows along a width direction of the first vibration arm A1. Alternatively, a plurality of first rate adjustment portions 43 may be arranged in a matrix or a grid. A shape, the number, an arrangement, and the like of the first rate adjustment portions 43 can be appropriately set according to the width Wa of the first opening 41 and a required etching depth.

### First Dry Etching Step S3

Next, as shown in FIG. 25, the quartz crystal substrate 200 is dry-etched from the upper surface 2a through the first protective film 4. Accordingly, the first groove A11 and the second groove A21 having different depths are collectively formed by using the micro loading effect. As described above, since the etching rate of the first groove formation region Qm1 is lower than the etching rate of the second groove formation region Qm2 by providing the first rate adjustment portions 43, the first groove A11 shallower than the second groove A21 can be formed. As shown in FIG. 26, for the first groove A11, as dry etching proceeds, the quartz crystal substrate 200 immediately below the first rate adjustment portions 43 is gradually removed, and finally, the first groove A11 as shown in FIG. 25 is formed. In particular, as in the embodiment, since a plurality of first rate adjustment portions 43 are arranged in an island shape, the first rate adjustment portions 43 can be made small. Since an entire periphery of each of the first rate adjustment portions 43 is etched, the quartz crystal substrate 200 immediately below the first rate adjustment portions 43 is easily removed.

### Second Protective Film Formation Step S4

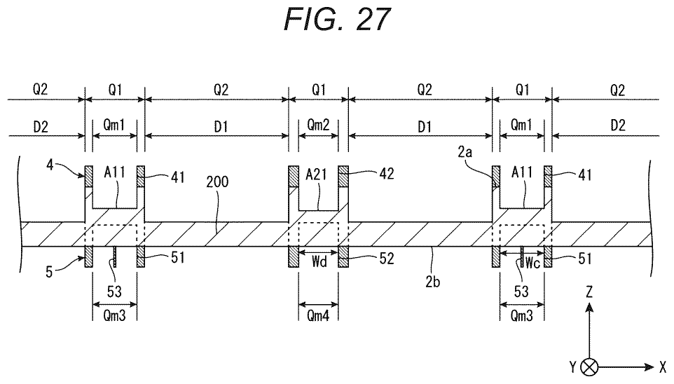

Next, as shown in FIG. 27, the second protective film 5 is formed on the lower surface 2b of the quartz crystal substrate 200. The second protective film 5 is formed on the element formation region Q1 and has the third opening 51 overlapping the third groove formation region Qm3 and the fourth opening 52 overlapping the fourth groove formation region Qm4. The width Wc of the third opening 51 is larger than the width Wd of the fourth opening 52. That is, Wc>Wd. Therefore, an etching rate of the third groove formation region Qm3 is higher than an etching rate of the fourth groove formation region Qm4, and the third groove A12 is deeper than the fourth groove A22 according to the micro loading effect. The second protective film 5 further includes second rate adjustment portions 53 located in the third opening 51. The second rate adjustment portion 53 has a function of reducing an etching rate of the third groove formation region Qm3. The second protective film 5 has the same structure as the first protective film 4.

As shown in FIG. 28, a plurality of second rate adjustment portions 53 are located at the center portion in the width direction of the third opening 51, and are disposed in a manner of being separated from one another along the extending direction of the first vibration arm A1. Dc<Wd, in which Dc represents a separation distance between an edge of the third opening 51 and the second rate adjustment portion 53. Dd<Wd, in which Dd represents a separation distance between the adjacent second rate adjustment portions 53. Accordingly, the third groove formation region Qm3 is denser than the fourth groove formation region Qm4, and even when We>Wd, an etching rate in the third groove formation region Qm3 can be made lower than an etching rate in the fourth groove formation region Qm4.

### Second Dry Etching Step S5

Next, as shown in FIG. 29, the quartz crystal substrate 200 is dry-etched from the lower surface 2b through the second protective film 5. Accordingly, the third groove A12 and the fourth groove A22 having different depths are collectively formed by using the micro loading effect. Similar to the above-described first groove A11, for the third groove A12, as dry etching proceeds, the quartz crystal substrate 200 immediately below the second rate adjustment portions 53 is gradually removed, and finally, the third groove A12 as shown in FIG. 29 is formed. A plurality of vibration substrates 2 are obtained from the quartz crystal substrate 200 by performing the above steps.

### Electrode Formation Step S6

Next, the electrode 3 is formed on a surface of the vibration substrate 2. Accordingly, the vibrator 100 is obtained.

According to such a manufacturing method, the first groove A11 and the second groove A21 having different depths can be collectively formed by using the micro loading effect. Similarly, the third groove A12 and the fourth groove A22 having different depths can be easily formed collectively by using the micro loading effect. A positional deviation of the grooves A11, A21, A12, and A22 relative to the outer shape of the vibration substrate 2 is prevented, and formation accuracy of the vibration substrate 2 is improved. In particular, since the shallow first and third grooves A11 and A12 can be made wider than the deep second and fourth grooves A21 and A22, the degree of freedom in design of the vibrator 100 increases.

As described above, the method for manufacturing the vibrator according to the embodiment is a method for manufacturing the vibrator 100. The vibrator 100 includes the first vibration arm A1 that has the upper surface 2a serving as the first surface and the lower surface 2b serving as the second surface which are in a front and back relationship and that has the bottomed first groove A11 opened in the upper surface 2a, and includes the second vibration arm A2 that has the bottomed second groove A21 opened in the upper surface 2a. The method for manufacturing the vibrator 100 includes: the preparation step S1 of preparing the quartz crystal substrate 200 having the upper surface 2a and the lower surface 2b, a first protective film formation step S2 of forming the first protective film 4 in the element formation region Q1 of the upper surface 2a; the first protective film 4 having the first opening 41 overlapping the first groove formation region Qm1, the first rate adjustment portions 43 located in the first opening 41, and the second opening 42 overlapping the second groove formation region Qm2, in which a region of the quartz crystal substrate 200 where the vibrator 100 is formed is referred to as the element formation region Q1, a region where the first groove A11 is formed is referred to as the first groove formation region Qm1, and a region where the second groove A21 is formed is referred to as the second groove formation region Qm2; and a first dry etching step S3 of dry etching the quartz crystal substrate 200 from the upper surface 2a through the first protective film 4. Da<Wb, in which Da represents a separation distance between an edge of the first opening 41 and the first rate adjustment portion 43 and Wb represents a width of the second opening 42. Accordingly, an etching rate of the first groove formation region Qm1 can be made lower than an etching rate of the second groove formation region Qm2 according to the micro loading effect. Therefore, the first and second grooves A11 and A21 having different depths can be collectively formed, and the vibrator 100 can be easily manufactured. In particular, the shallow first groove A11 can be made wider than the deep second groove A21. Since the first and second grooves A11 and A21 are formed together with the outer shape, a positional deviation of the first and second grooves A11 and A21 relative to the outer shape is prevented, and formation accuracy of the vibrator 100 is improved.

As described above, the vibrator 100 includes the third groove A12 opened in the lower surface 2b of the first vibration arm A1 and the fourth groove A22 opened in the lower surface 2b of the second vibration arm A2, and the method for manufacturing the vibrator 100 includes: the second protective film formation step S4 of forming the second protective film 5 in the element formation region Q1 of the lower surface 2b, the second protective film 5 having the third opening 51 overlapping the third groove formation region Qm3, the second rate adjustment portions 53 located in the third opening 51, and the fourth opening 52 overlapping the fourth groove formation region Qm4, in which a region of the quartz crystal substrate 200 where the third groove A12 is formed is referred to as the third groove formation region Qm3, and a region where the fourth groove A22 is formed is referred to as the fourth groove formation region Qm4; and the second dry etching step S5 of dry etching the quartz crystal substrate 200 from the lower surface 2b through the second protective film 5. Dc<Wd, in which Dc represents a separation distance between an edge of the third opening 51 and the second rate adjustment portion 53 and Wd represents a width of the fourth opening 52. Accordingly, an etching rate of the third groove formation region Qm3 can be made lower than an etching rate of the fourth groove formation region Qm4 according to the micro loading effect. Therefore, the third and fourth grooves A12 and A22 having different depths can be collectively formed, and the vibrator 100 can be easily manufactured. In particular, the shallow third groove A12 can be made wider than the deep fourth groove A22.

As described above, a plurality of first rate adjustment portions 43 are arranged in a manner of being separated from one another along the extending direction of the first vibration arm A1. Db<Wb, in which db represents a separation distance between a pair of adjacent first rate adjustment portions 43. Accordingly, the quartz crystal substrate 200 immediately below the first rate adjustment portions 43 is easily removed in the first dry etching step S3.

The third embodiment as described above can also exhibit the same effect as the first embodiment described above.

### Fourth Embodiment

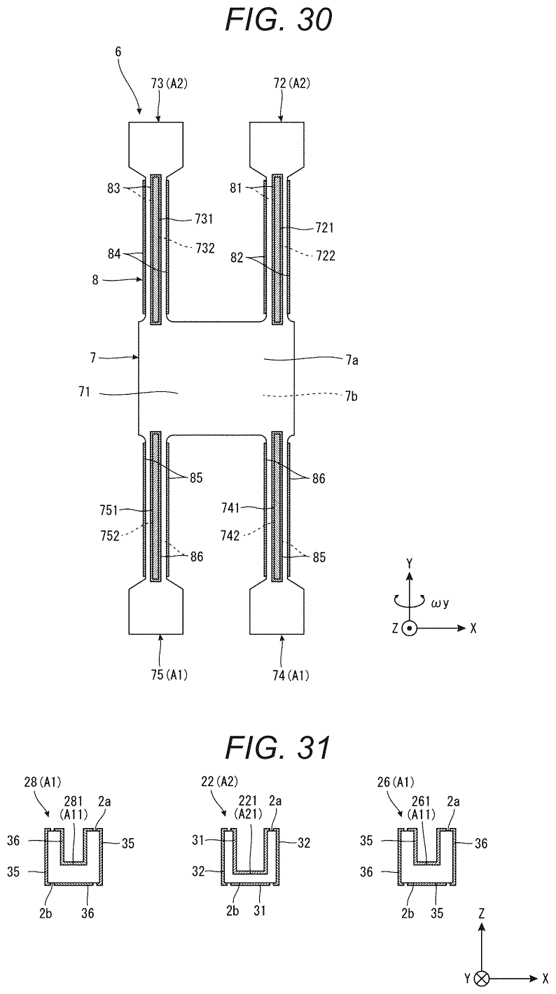

FIG. 30 is a plan view showing a vibrator according to a fourth embodiment.

The method for manufacturing the vibrator according to the embodiment is similar to the method for manufacturing the vibrator according to the first embodiment described above except that a configuration of the vibrator to be manufactured is different. In the following description, the method for manufacturing the vibrator according to the embodiment will be described with a focus on differences from the first embodiment described above, and description of similar matters will be omitted. In the drawings of the embodiment, configurations the same as those of the above embodiment will be denoted by the same reference numerals.

In the method for manufacturing the vibrator according to the embodiment, a vibrator 6 shown in FIG. 30 is manufactured. The vibrator 6 is an angular velocity detection element capable of detecting an angular velocity cry around the Y axis. The vibrator 6 includes a vibration substrate 7 formed by patterning a Z-cut quartz crystal substrate, and an electrode 8 formed on a surface of the vibration substrate 7.

The vibration substrate 7 has a plate shape and has an upper surface 7a serving as a first surface and a lower surface 7b serving as a second surface which are in a front and back relationship. The vibration substrate 7 includes a base portion 71 located in a center portion of the vibration substrate 7, a pair of detection vibration arms 72 and 73 serving as the second vibration arm A2 extending from the base portion 71 to a positive side of the Y-axis direction, and a pair of drive vibration arms 74 and 75 serving as the first vibration arm A1 extending from the base portion 71 to a negative side of the Y-axis direction. The pair of detection vibration arms 72 and 73 are arranged side by side in the X-axis direction, and the pair of drive vibration arms 74 and 75 are arranged side by side in the X-axis direction.

The detection vibration arm 72 has a bottomed groove 721 serving as a second groove formed in the upper surface 7a and a bottomed groove 722 serving as a fourth groove formed in the lower surface 7b. Similarly, the detection vibration arm 73 has a bottomed groove 731 serving as the second groove formed in the upper surface 7a and a bottomed groove 732 serving as the fourth groove formed in the lower surface 7b.

The drive vibration arm 74 has a bottomed groove 741 serving as a first groove formed in the upper surface 7a and a bottomed groove 742 serving as a third groove formed in the lower surface 7b. Similarly, the drive vibration arm 75 has a bottomed groove 751 serving as the first groove formed in the upper surface 7a and a bottomed groove 752 serving as the third groove formed in the lower surface 7b.

The electrode 8 includes a first detection signal electrode 81, a first detection ground electrode 82, a second detection signal electrode 83, a second detection ground electrode 84, a drive signal electrode 85, and a drive ground electrode 86.

Among the electrodes, the first detection signal electrode 81 is disposed on the upper surface 7a and the lower surface 7b of the detection vibration arm 72, and the first detection ground electrode 82 is disposed on both side surfaces of the detection vibration arm 72. The second detection signal electrode 83 is disposed on the upper surface 7a and the lower surface 7b of the detection vibration arm 73, and the second detection ground electrode 84 is disposed on both side surfaces of the detection vibration arm 73. The drive signal electrode 85 is disposed on the upper surface 7a and the lower surface 7b of the drive vibration arm 74 and on both side surfaces of the drive vibration arm 75, and the drive ground electrode 86 is disposed on both side surfaces of the drive vibration arm 74 and on the upper surface 7a and the lower surface 7b of the drive vibration arm 75.

The fourth embodiment as described above can also exhibit the same effect as the first embodiment described above.

Although the method for manufacturing the vibrator element according to the present disclosure has been described above based on the illustrated embodiments, the present disclosure is not limited thereto. A configuration of each part can be replaced with any configuration having the same function. Any other components or steps may be added to the present disclosure. The vibrator is not limited to the vibrators 1 and 6 described above, and may be, for example, a tuning fork type vibrator or a double-tuning fork type vibrator. The vibrator is not limited to an angular velocity detection element.

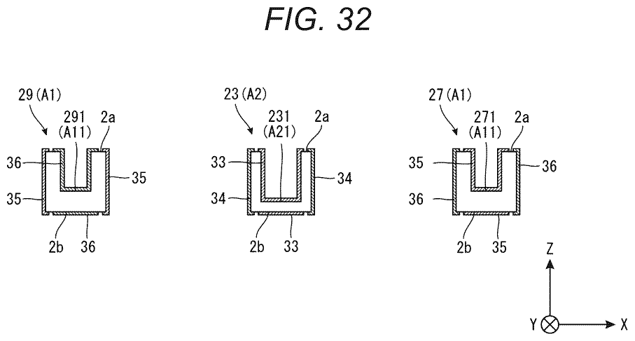

In the vibrator 1, for example, the third and fourth grooves A12 and A22 may be omitted as shown in FIGS. 31 and 32. In this case, the method for manufacturing the vibrator 1 includes the preparation step S1, the first protective film formation step S2, the first dry etching step S3, and the electrode formation step S6. In the first dry etching step S3, the removal region Q2 of the quartz crystal substrate 200 may be etched through. According to such a configuration, the vibration substrate 2 can be formed by performing dry etching from the upper surface 2a only. Therefore, the vibrator 1 is more easily manufactured.

For example, the first rate adjustment portions 43 may be used in the first embodiment and the second embodiment. Accordingly, the first groove A11 can be made shallower. That is, the first rate adjustment portions 43 can be used for purposes other than a purpose of forming the first groove A11 to be wider than the second groove A21. The same applies to the second rate adjustment portions 53.

What is claimed is:

1. A method for manufacturing a vibrator, the vibrator including a first vibration arm that has a first surface and a second surface which are in a front and back relationship and that has a bottomed first groove opened in the first surface, and a second vibration arm that has a bottomed second groove opened in the first surface, the method comprising:
a preparation step of preparing a quartz crystal substrate having the first surface and the second surface;
a first protective film formation step of forming a first protective film in an element formation region of the first surface, the first protective film having a first opening overlapping a first groove formation region and a second opening overlapping a second groove formation region, in which a region of the quartz crystal substrate where the vibrator is formed is referred to as the element formation region, a region where the first groove is formed is referred to as the first groove formation region, and a region where the second groove is formed is referred to as the second groove formation region; and
a first dry etching step of dry etching the quartz crystal substrate from the first surface through the first protective film, wherein
Wa<Wb, in which Wa represents a width of the first opening and Wb represents a width of the second opening.

2. The method for manufacturing the vibrator according to claim 1, wherein
the first protective film has a plurality of the first openings arranged side by side in a direction orthogonal to an extending direction of the first vibration arm.

3. The method for manufacturing the vibrator according to claim 1, wherein
the vibrator has a third groove opened in the second surface of the first vibration arm and a fourth groove opened in the second surface of the second vibration arm,
the method further comprises:
a second protective film formation step of forming a second protective film in the element formation region of the second surface, the second protective film having a third opening overlapping a third groove formation region and a fourth opening overlapping a fourth groove formation region, in which a region of the quartz crystal substrate where the third groove is formed is referred to as the third groove formation region, and a region where the fourth groove is formed is referred to as the fourth groove formation region; and
a second dry etching step of dry etching the quartz crystal substrate from the second surface through the second protective film, and
Wc<Wd, in which Wc represents a width of the third opening and Wd represents a width of the fourth opening.

4. A method for manufacturing a vibrator, the vibrator including a first vibration arm that has a first surface and a second surface which are in a front and back relationship and that has a bottomed first groove opened in the first surface, and a second vibration arm that has a bottomed second groove opened in the first surface, the method comprising:
a preparation step of preparing a quartz crystal substrate having the first surface and the second surface;
a first protective film formation step of forming a first protective film in an element formation region of the first surface, the first protective film having a first opening overlapping a first groove formation region, a first rate adjustment portion located in the first opening, and a second opening overlapping a second groove formation region, in which a region of the quartz crystal substrate where the vibrator is formed is referred to as the element formation region, a region where the first groove is formed is referred to as the first groove formation region, and a region where the second groove is formed is referred to as the second groove formation region; and
a first dry etching step of dry etching the quartz crystal substrate from the first surface through the first protective film, wherein
Da<Wb, in which Da represents a separation distance between an edge of the first opening and the first rate adjustment portion and Wb represents a width of the second opening.

5. The method for manufacturing the vibrator according to claim 4, wherein
the vibrator has a third groove opened in the second surface of the first vibration arm and a fourth groove opened in the second surface of the second vibration arm,
the method further comprises:
a second protective film formation step of forming a second protective film in the element formation region of the second surface, the second protective film having a third opening overlapping a third groove formation region, a second rate adjustment portion located in the third opening, and a fourth opening overlapping a fourth groove formation region, in which a region of the quartz crystal substrate where the third groove is formed is referred to as the third groove formation region, and a region where the fourth groove is formed is referred to as the fourth groove formation region; and
a second dry etching step of dry etching the quartz crystal substrate from the second surface through the second protective film, and
Dc<Wd, in which Dc represents a separation distance between an edge of the third opening and the second rate adjustment portion, and Wd represents a width of the fourth opening.

6. The method for manufacturing the vibrator according to claim 4, wherein
a plurality of the first rate adjustment portions are arranged in a manner of being separated from one another along an extending direction of the first vibration arm, and
Db<Wb, in which db represents a separation distance between a pair of the adjacent first rate adjustment portions.

7. The method for manufacturing the vibrator according to claim 1, wherein
the vibrator is an angular velocity detection element configured to detect an angular velocity,
the first vibration arm performs a flexural vibration in response to an applied drive signal, and
the second vibration arm performs a flexural vibration in response to an applied angular velocity.

8. The method for manufacturing the vibrator according to claim 7, wherein
the vibrator includes a base portion, a pair of the second vibration arms extending from the base portion to both sides in a first direction, a pair of support arms extending from the base portion to both sides in a second direction intersecting the first direction, a pair of the first vibration arms extending from one of the support arms to both sides in the first direction, and a pair of the first vibration arms extending from the other one of the support arms to both sides in the first direction.
